(19) United States
(12) Patent Application Publication
(10) Pub. No.: US 2005/0153498 A1
(43) Pub. Date: Jul. 14, 2005

(54) Method of manufacturing p-channel MOS transistor and CMOS transistor

(75) Inventor: Hak-Dong Kim, Suwon-city (KR)

Correspondence Address: OBLON, SPIVAK, MCCLELLAND, MAIER & NEUSTADT, P.C., 1940 DUKE STREET, ALEXANDRIA, VA, 22314, US

(73) Assignee: DongbuAnam Semiconductor Inc., Seoul (KR)

(21) Appl. No.: 11/020,096

(22) Filed: Dec. 27, 2004

(30) Foreign Application Priority Data
Dec. 27, 2003 (KR) 10-2003-0098380

(51) Int. Cl. H01L 21/336; H01L 21/8234; H01L 21/8238

(52) U.S. Cl. 438/197; 438/199; 438/302; 438/303; 438/306

(57) ABSTRACT

A method of manufacturing a p-channel MOS transistor including forming a structure by subsequently stacking gate insulating layer pattern and a gate conductive layer pattern on a semiconductor substrate. The method also includes forming first offset spacer layers on sides of the gate conductive layer pattern, forming a second-offset-spacer-layer insulating layer to cover the semiconductor substrate, the first offset spacer layer, and the gate conductive layer pattern, implanting p-type impurity ions in the second-offset-spacer-layer insulating layer by performing a first ion implanting process, and forming a second offset spacer layer and a gate spacer layer on the first offset spacer layer by performing a spacer layer forming process. The method further includes forming source/drain extension regions by diffusing the implanted p-type impurity ions by performing a thermal treatment process, and forming source/drain regions passing through the respective source/drain extension regions by performing a second ion implanting process by using the gate spacer layer as an ion implanting barrier.

### BACKGROUND OF THE INVENTION

1. Field of the Invention

The present invention relates to a method of manufacturing a MOS transistor, and more particularly, to a method of manufacturing a p-channel MOS transistor and a CMOS transistor.

2. Description of the Related Art

FIGS. 1 to 5 are cross sectional views for explaining a method of manufacturing a related art p-channel MOS transistor.

Referring to FIG. 1, an active region where a MOS transistor is to be formed is defined by forming an element isolation layer 110 on an n-type semiconductor substrate 100. Alternatively, instead of the n-type semiconductor substrate 100, a p-type semiconductor substrate may be used. In this case, an n-type well region is formed on the p-type semiconductor substrate.

Next, a gate stack is formed by subsequently stacking a gate insulating layer pattern 120 and a gate conductive layer pattern 130 on the active region of the substrate 100. The gate stack is disposed to cover a channel region in an upper portion of the semiconductor substrate 100.

Referring to FIG. 2, in order to reduce a short channel effect, a halo ion implanting process is performed. As a result, a halo impurity region 141 is formed to surround a channel region under the gate insulating layer pattern 120 by implanting n-type impurity ions in the substrate 100 in a slanted direction thereof.

Referring to FIG. 3, a first ion implanting process is performed by implanting p-type impurity ions in the substrate 100. As a result, source/drain extension regions 142 are formed in the substrate at both sides of the gate 130. In some cases, the first ion implanting process may be performed prior to the halo ion implanting process.

In addition, although not shown in the figure, an oxide layer may be formed as an ion implanting buffer layer on a surface of the substrate 100 prior to the first ion implanting process.

Referring to FIG. 4, gate spacer layers 150 are formed on side walls of the gate conductive layer 130. Next, a second ion implanting process is performed by implanting p-type impurity ions by using the gate spacer layers 150 as an ion implanting barrier. As a result, source/drain regions 143 are formed in the substrate 100 at the respective sides of the gate spacer layers 150.

Referring to FIG. 5, a MOS transistor is completed by performing a general silicide process forming metal silicide layers 160 on the source/drain regions 143 and the gate conductive layer pattern 130 and subsequently performing a general metallization process.

In the method of manufacturing a related art p-channel MOS transistor, boron (B) ions have been used as impurity ions for an ion implanting process for forming the source/drain regions 143. In addition, after the B ions are implanted, the implanted B ions are diffused by performing a thermal treatment process. However, since it is difficult to effectively control a transient enhanced diffusion (TED) effect that the implanted B ions are rapidly diffused during the thermal treatment process, there is a problem in that a short channel effect (SCE) that a threshold voltage in the short channel is too sharply lowered may increase.

In addition, there is another problem in that performance such as switching speed of a low-power high-speed low-voltage device may be deteriorated due to parasite resistance. In particular, in a CMOS transistor, the channel length of the n-channel MOS transistor becomes shorter than that of the p-channel MOS transistor due to the TED effect of the B ions, so that the short channel effect of the p-channel MOS transistor may be more predominant than that of the n-channel MOS transistor.

### SUMMARY OF THE INVENTION

In order to solve the aforementioned problems, the present invention advantageously provides a method of manufacturing a p-channel MOS transistor and a CMOS transistor capable of preventing device performance from be deteriorated by suppressing a short channel effect and reducing parasite resistance in the p-channel MOS transistor.

According to an aspect of the present invention, there is provided a method of manufacturing a p-channel MOS transistor, comprising steps of forming a structure by subsequently stacking gate insulating layer pattern and a gate conductive layer pattern on a semiconductor substrate, forming first offset spacer layers on sides of the gate conductive layer pattern; forming a second-offset-spacer-layer insulating layer to cover the semiconductor substrate, the first offset spacer layer, and the gate conductive layer pattern, and implanting p-type impurity ions in the second-offset-spacer-layer insulating layer by performing a first ion implanting process. The method further comprises the steps of forming a second offset spacer layer and a gate spacer layer on the first offset spacer layer by performing a spacer layer forming process, forming source/drain extension regions by diffusing the implanted p-type impurity ions by performing a thermal treatment process, and forming source/drain regions passing through the respective source/drain extension regions by performing a second ion implanting process by using the gate spacer layer as an ion implanting barrier.

In the above aspect of the present invention, the first offset spacer layer and the second-offset-spacer-layer insulating layer may be oxide layers.

In addition, the oxide layer for the first offset spacer layer and the second-offset-spacer-layer insulating layer may have a thickness of about 50 to about 200 Å.

In addition, the p-type impurity ions may be BF₂ ions, and the first ion implanting process may be performed by implanting BF₂ ions with an implanting energy of about 3 to about 50 keV and a concentration of about 1×10¹⁴ to about 1×10¹⁵ ions/cm².

In addition, the thermal treatment process may be performed at a temperature of about 800 to about 1000° C. in N₂ ambience for about 10 to about 30 seconds.

In addition, the method may further comprise a step of performing a halo ion implanting process for implanting n-type impurity ions prior to the first ion implanting process.

In addition, the halo ion implanting process may be performed by implanting arsenic (As) ions at a slanted angle of about 20 to about 40 degrees with an implanting energy of about 10 to about 50 keV and a concentration of about 1×10¹³ to about 5×10¹⁴ ions/cm².

According to another aspect of the present invention, there is provided a method of manufacturing a CMOS transistor, comprising steps of preparing a semiconductor substrate having a first region where an n-channel MOS transistor is to be disposed and a second region where a p-channel MOS transistor is to be disposed, forming a first structure by subsequently stacking a first gate insulating layer pattern and a first gate conductive layer pattern on the first region of the semiconductor substrate and a second structure by subsequently stacking a second gate insulating layer pattern and a second gate conductive layer pattern on the second region of the semiconductor substrate, and forming offset spacer layers on sides of the first and second gate conductive layer patterns. The method further comprises the steps of forming first source/drain extension regions on the first region of the semiconductor substrate by using a mask film pattern for exposing the first region and covering the second region, forming second-offset-spacer-layer insulating layers on entire surfaces of the first and second regions, forming a mask film pattern to cover the first region and expose the second region, and implanting p-type impurity ions in the second-offset-spacer-layer insulating layer of the second region by performing a first ion implanting process. The method also comprises the steps of removing the mask film pattern, forming second offset spacer layers and gate spacer layers on the respective first and second offset spacer layers of the respective first and second regions, forming second source/drain extension regions by diffusing the p-type impurity ions implanted in the second-offset-spacer-layer insulating layer of the second region into the second region of the semiconductor substrate by performing a thermal treatment process, and forming first and second source/drain regions of the respective first and second regions by performing an ion implanting process by using the gate spacer layers as a second ion implanting barrier.

### BRIEF DESCRIPTION OF THE DRAWINGS

The above and other features and advantages of the present invention will become more apparent by describing in detail exemplary embodiments thereof with reference to the attached drawings in which:

FIGS. 1 to 5 are cross sectional views for explaining a related art p-channel MOS transistor; and

FIGS. 6 to 12 are cross sectional views for explaining a p-channel MOS transistor and a CMOS transistor according to embodiments of the present invention.

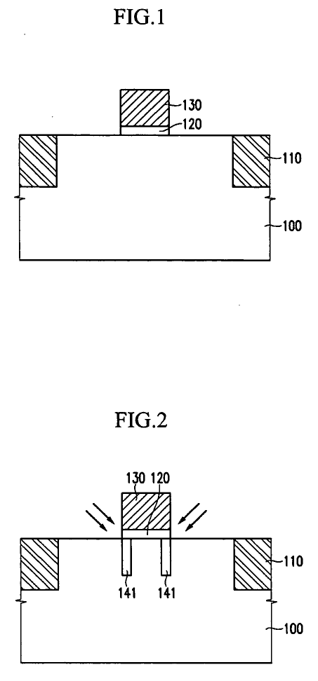

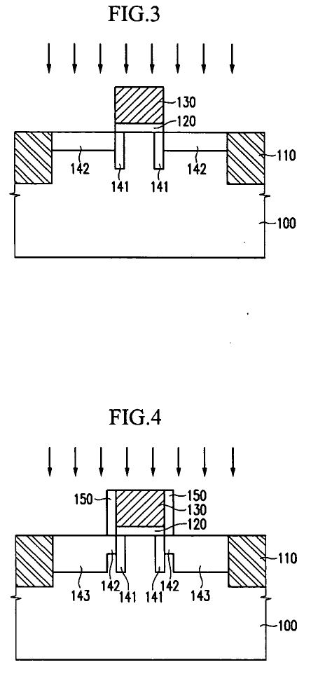

### DETAILED DESCRIPTION OF THE INVENTION

Now, exemplary embodiments of the present invention will be described with reference to the attached drawings. However, the present invention can be embodied in various modifications and thus is not limited to the embodiments described below.

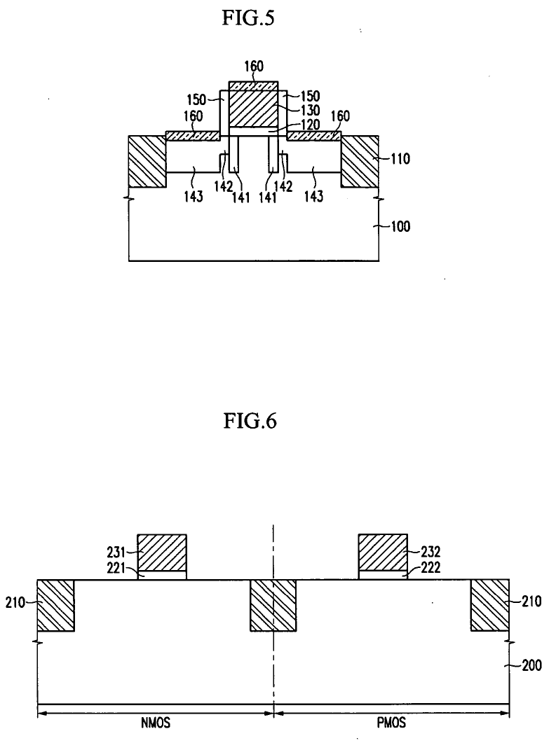

FIGS. 6 to 12 are cross sectional views for explaining a p-channel MOS transistor and a CMOS transistor according to embodiments of the present invention.

Referring to FIG. 6, a silicon semiconductor substrate 200 has a first region NMOS where an n-channel MOS transistor is to be disposed and a second region PMOS where a p-channel MOS transistor is to be disposed. Active regions of the first and second regions NMOS and PMOS are defined by forming an element isolation layer 210 on the semiconductor substrate 200. In addition, the element isolation layer 210 has a function of electrically isolating the first and second regions NMOS and PMOS.

Next, a gate oxide layer having a thickness of about 10 to about 50 Å and a gate conductive layer having a thickness of about 100 to about 300 Å are subsequently formed on the semiconductor substrate 200. Next, some portions of the gate oxide layer and the gate conductive layer are removed by using a predetermined mask film pattern.

As a result, a first structure where a first gate oxide layer 221 and a first gate conductive layer pattern 231 are subsequently stacked on the first region NMOS of the semiconductor substrate 200 is obtained. In addition, a second structure where a second gate oxide layer 222 and a second gate conductive layer pattern 232 are subsequently stacked on the second region PMOS of the semiconductor substrate 200 is obtained.

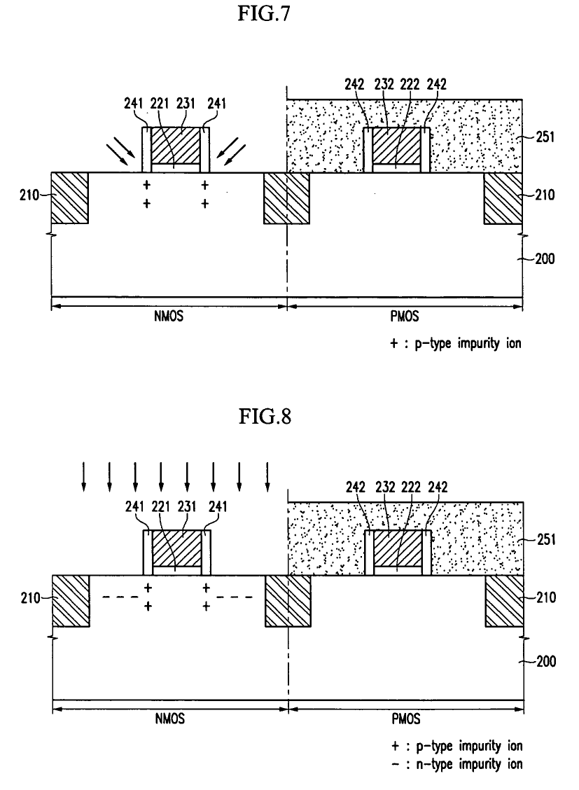

Referring to FIG. 7, first and second offset spacer layers 241 and 242 are formed on the respective side walls of the first and second gate conductive layer pattern 231 and 232, respectively. The first and second offset spacer layers 241 and 242 are an oxide layer formed by using a low temperature CVD (chemical vapor depositing) method. More specifically, an oxide layer having a thickness of about 50 to about 200 Å is formed on the entire surface of the resultant structure and an anisotropic etching process such as an etch-back process is performed to form the first and second offset spacer layers 241 and 242.

Next, a first mask film pattern 251 such as a photoresist film pattern is formed to expose the first region NMOS and cover the second region PMOS.

Next, a halo ion implanting process is performed by implanting p-type impurity ions in the vicinity of the channel region of the first region NMOS as indicated by arrows of the figure. Here, boron (B) ions are used as the p-type impurity ions. The B ions implanted at a slanted angle of about 20 to about 40 degrees with an implanting energy of about 10 to about 50 keV and a concentration of about 1×10¹³ to about 5×10¹⁴ ions/cm².

Referring to FIG. 8, first source/drain extension regions are formed by implanting n-type impurity ions with a second ion implanting process as indicated by arrows of the figure. Here, arsenic (As) ions are used as the n-type impurity ions. The As ions implanted with an implanting energy of about 5 to about 50 keV and a concentration of about 1×10¹⁴ to about 1×10¹⁵ ions/cm².

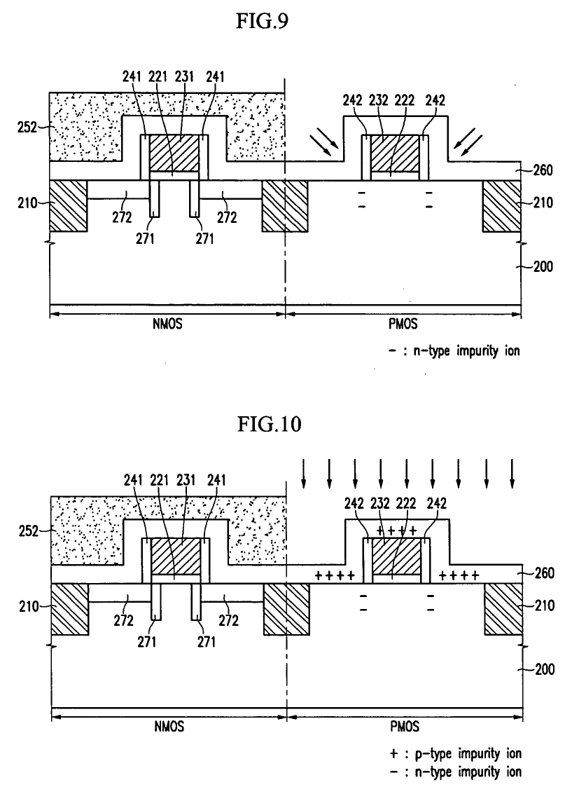

Referring to FIG. 9, the first mask film pattern 251 (see FIG. 8) is removed, and a second-offset-spacer-layer oxide layer 260 is formed on the entire surfaces of the first and second regions NMOS and PMOS. The second-offset-spacer-layer oxide layer 260 is formed to have a thickness of about 50 to about 200 Å by using a furnace. During the formation of the second-offset-spacer-layer oxide layer 260, the impurity ions implanted in the first region NMOS are diffused to form a first halo region 271 and source/drain extension regions 272.

Next, a second mask film pattern 252 such as a photoresist film pattern is formed on the second-offset-spacer-layer oxide layer 260 to cover the second-offset-spacer-layer oxide layer 260 of the first region NMOS and expose the second-offset-spacer-layer oxide layer 260 of the second region PMOS.

Next, another halo ion implanting process is performed by implanting n-type impurity ions in the vicinity of the channel region of the second region PMOS as indicated by arrows of the figure. Here, As ions are used as the n-type impurity ions. The As ions implanted at a slanted angle of about 20 to about 40 degrees with an implanting energy of about 10 to about 50 keV and a concentration of about 1×10¹³ to about 5×10¹⁴ ions/cm².

Referring to FIG. 10, second source/drain extension regions are formed by implanting p-type impurity ions with a third ion implanting process as indicated by arrows of the figure. More specifically, the p-type impurity ions are implanted in the second-offset-spacer-layer oxide layer 260. Here, in a case where BF₂ ions are used as the n-type impurity ions, the BF₂ ions implanted with an implanting energy of about 3 to about 50 keV and a concentration of about 1×10¹⁴ to about 1×10¹⁵ ions/cm².

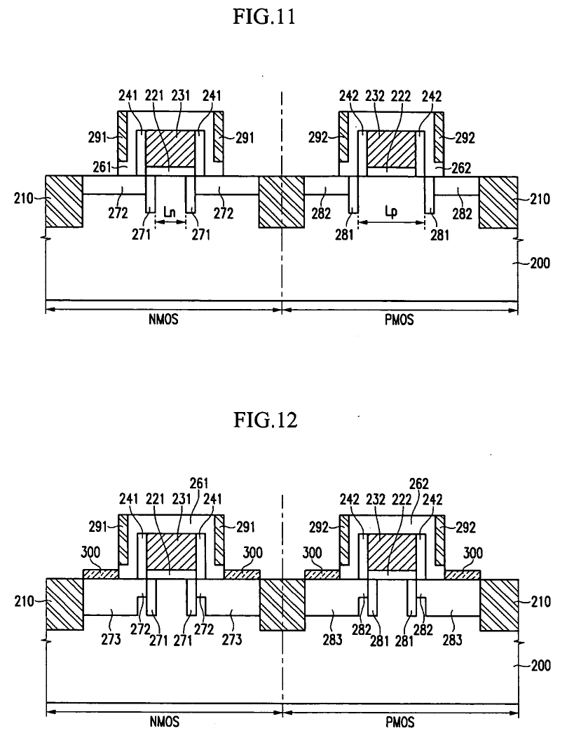

Referring to FIG. 11, the mask film pattern 252 (see FIG. 10) is removed, and a gate-spacer-layer nitride layer (not shown) having a thickness of about 600 to about 2000 Å is formed on the second-offset-spacer-layer oxide layer 260 (see FIG. 10). Next, a first offset spacer layer 261 and a first gate spacer layer 291 of the first region NMOS and a second offset spacer layer 262 and a second gate spacer layer 292 of the second region PMOS are formed by using a general anisotropic etching process such as an etch-back process.

Next, the implanted impurity ions are diffused by performing a thermal treatment process. The thermal treatment process is an RTP (rapid thermal processing) process performed at a temperature of about 800 to about 1000° C. in N₂ ambience for about 10 to about 30 seconds.

As a result of the thermal treatment process, as shown in the figure, the p-type impurity ions implanted in the second-offset-spacer-layer oxide layer 260 (see FIG. 10) of the second region PMOS are diffused into the semiconductor substrate 200 to form a second halo region 281 and source/drain extension regions 282.

As described above with reference to FIG. 10, since the p-type impurity ions, that is, the B ions are implanted into the second-offset-spacer-layer oxide layer 260 (see FIG. 10) during the ion implanting process for the second region PMOS, the channel length L_{P} of the second region PMOS becomes longer than the channel length L_{N} of the first region NMOS. Accordingly, although the diffusion speed of the B ions is high, the channel length L_{P} of the second region PMOS becomes longer than the channel length L_{N} of the first region NMOS.

Referring to FIG. 12, first source/drain regions 273 of the first region NMOS and the second source/drain regions 283 are formed in the semiconductor substrate 200 by using general respective ion implanting processes.

The ion implanting process forming the first source/drain regions 273 is performed by implanting As ions with an implanting energy of about 5 to about 50 keV and a concentration of about 1×10¹⁵ to about 5×10¹⁵ ions/cm². In addition, the ion implanting process forming the second source/drain regions 283 is performed by implanting B ions with an implanting energy of about 3 to about 50 keV and a concentration of about 1×10¹⁴ to about 5×10¹⁵ ions/cm².

Next, the implanted impurity ions are diffused by performing an RTP process performed at a temperature of about 900 to about 1050° C. in N₂ ambience for about 10 to about 30 seconds. In the ion implanting process forming the first source/drain regions 273, a mask film pattern (not shown) is used to cover the second region PMOS. Similarly, in the ion implanting process forming the second source/drain regions 283, a mask film pattern (not shown) is used to cover the first region NMOS.

Next, metal silicide layers 300 are formed by a general silicide process. As a result, the metal silicide layer 300 are formed on the first source/drain regions 273 of the first region NMOS and the second source/drain regions 283 of the second region PMOS. Although not shown in the figure, the metal silicide layers 300 are also formed on some portions of the surfaces of the first and second gate conductive layer patterns 231 and 232. Next, although not shown in the figure, metallization layers are formed by performing a general metallization process.

As described above, according to a method of manufacturing a p-channel MOS transistor and a CMOS transistor, a second gate conductive layer pattern is formed during an ion implanting process for forming source/drain extension regions, a channel length of the n-channel MOS transistor becomes longer than that of the p-channel MOS transistor irrespective of the high diffusion speed of boron (B) ions. Therefore, it is possible to suppress the short channel effect of the p-channel MOS transistor. In addition, since impurity ions are implanted in the second gate conductive layer pattern, so that the second gate conductive layer pattern can be heavily doped. Therefore, it is possible to effectively suppress parasite resistance.

Korean Patent Application No. 10-2003-0098380, filed on Dec. 27, 2003, is hereby incorporated by reference in its entirety.

While the present invention has been particularly shown and described with reference to exemplary embodiments thereof, it will be understood by those skilled in the art that various changes in form and details may be made therein without departing from the spirit and scope of the invention as defined by the appended claims.

1. A method of manufacturing a p-channel MOS transistor, comprising steps of:
forming a structure by subsequently stacking gate insulating layer pattern and a gate conductive layer pattern on a semiconductor substrate;
forming first offset spacer layers on sides of the gate conductive layer pattern;
forming a second-offset-spacer-layer insulating layer to cover the semiconductor substrate, the first offset spacer layers, and the gate conductive layer pattern;
implanting p-type impurity ions in the second-offset-spacer-layer insulating layer by performing a first ion implanting process;
forming a second offset spacer layer and a gate spacer layer on the first offset spacer layers by performing a spacer layer forming process;
forming source/drain extension regions by diffusing the implanted p-type impurity ions by performing a thermal treatment process; and
forming source/drain regions passing through the respective source/drain extension regions by performing a second ion implanting process by using the gate spacer layer as an ion implanting barrier.

2. The method of claim 1, wherein the first offset spacer layer and the second-offset-spacer-layer insulating layer are oxide layers.

3. The method of claim 2, wherein the oxide layer for the first offset spacer layer and the second-offset-spacer-layer insulating layer have a thickness of about 50 to about 200 Å.

4. The method of claim 1,
wherein the p-type impurity ions are BF₂ ions, and
wherein the first ion implanting process is performed by implanting BF₂ ions with an implanting energy of about 3 to about 50 keV and a concentration of about 1×10¹⁴ to about 1×10¹⁵ ions/cm².

5. The method of claim 1, wherein the thermal treatment process is performed at a temperature of about 800 to about 1000° C. in N₂ ambience for about 10 to about 30 seconds.

6. The method of claim 1, further comprising a step of performing a halo ion implanting process for implanting n-type impurity ions prior to the first ion implanting process.

7. The method of claim 6, wherein the halo ion implanting process is performed by implanting arsenic (As) ions at a slanted angle of about 20 to about 40 degrees with an implanting energy of about 10 to about 50 keV and a concentration of about 1×10¹³ to about 5×10¹⁴ ions/cm².

8. A method of manufacturing a CMOS transistor, comprising steps of:
preparing a semiconductor substrate having a first region where an n-channel MOS transistor is to be disposed and a second region where a p-channel MOS transistor is to be disposed;
forming a first structure by subsequently stacking a first gate insulating layer pattern and a first gate conductive layer pattern on the first region of the semiconductor substrate and a second structure by subsequently stacking a second gate insulating layer pattern and a second gate conductive layer pattern on the second region of the semiconductor substrate;
forming offset spacer layers on sides of the first and second gate conductive layer patterns;
forming first source/drain extension regions on the first region of the semiconductor substrate by using a mask film pattern for exposing the first region and covering the second region;
forming second-offset-spacer-layer insulating layers on entire surfaces of the first and second regions;
forming a mask film pattern to cover the first region and expose the second region;
implanting p-type impurity ions in the second-offset-spacer-layer insulating layer of the second region by performing a first ion implanting process;
removing the mask film pattern;
forming second offset spacer layers and gate spacer layers on the respective first and second offset spacer layers of the respective first and second regions;
forming second source/drain extension regions by diffusing the p-type impurity ions implanted in the second-offset-spacer-layer insulating layer of the second region into the second region of the semiconductor substrate by performing a thermal treatment process; and
forming first and second source/drain regions of the respective first and second regions by performing an ion implanting process by using the gate spacer layers as a second ion implanting barrier.

9. The method of claim 8, wherein the first offset spacer layer and the second-offset-spacer-layer insulating layer are oxide layers.

10. The method of claim 9, wherein the oxide layer for the first offset spacer layer and the second-offset-spacer-layer insulating layer have a thickness of about 50 to about 200 Å.

11. The method of claim 8,
wherein the p-type impurity ions are BF₂ ions, and
wherein the first ion implanting process is performed by implanting BF₂ ions with an implanting energy of about 3 to about 50 keV and a concentration of about 1×10¹⁴ to about 1×10 ¹⁵ ions/cm².

12. The method of claim 8, wherein the thermal treatment process is performed at a temperature of about 800 to about 1000° C. in N₂ ambience for about 10 to about 30 seconds.

13. The method of claim 8, further comprising a step of performing a halo ion implanting process for implanting n-type impurity ions prior to the first ion implanting process.

14. The method of claim 13, wherein the halo ion implanting process is performed by implanting arsenic (As) ions with an implanting energy of about 10 to about 50 keV and a concentration of about 1×10¹³ to about 5×10¹⁴ ions/cm².

15. The method of claim 8, wherein the mask film pattern is formed by using photoresist.

16. A method of manufacturing a p-channel MOS transistor, comprising:
a step for forming a structure by subsequently stacking gate insulating layer pattern and a gate conductive layer pattern on a semiconductor substrate;
a step for forming first offset spacer layers on sides of the gate conductive layer pattern;
a step for forming a second-offset-spacer-layer insulating layer to cover the semiconductor substrate, the first offset spacer layers, and the gate conductive layer pattern;
a step for implanting p-type impurity ions in the second-offset-spacer-layer insulating layer by performing a first ion implanting process;
a step for forming a second offset spacer layer and a gate spacer layer on the first offset spacer layers by performing a spacer layer forming process;
a step for forming source/drain extension regions by diffusing the implanted p-type impurity ions by performing a thermal treatment process; and
a step for forming source/drain regions passing through the respective source/drain extension regions by performing a second ion implanting process by using the gate spacer layer as an ion implanting barrier.

17. The method of claim 16, wherein the first offset spacer layer and the second-offset-spacer-layer insulating layer are oxide layers.

18. The method of claim 17, wherein the oxide layer for the first offset spacer layer and the second-offset-spacer-layer insulating layer have a thickness of about 50 to about 200 Å.

19. The method of claim 16,
wherein the p-type impurity ions are BF₂ ions, and
wherein the first ion implanting process is performed by implanting BF₂ ions with an implanting energy of about 3 to about 50 keV and a concentration of about 1×10¹⁴ to about 1×10¹⁵ ions/cm².

20. The method of claim 16, wherein the thermal treatment process is performed at a temperature of about 800 to about 1000° C. in N₂ ambience for about 10 to about 30 seconds.
